(19) United States
(12) Patent Application Publication
(10) Pub. No.: US 2026/0047405 A1
(43) Pub. Date: Feb. 12, 2026

(54) PILLAR SPACER MERGING PATTERNING

(71) Applicant: Tokyo Electron Limited, Tokyo (JP)

(72) Inventors: Eric Chih-Fang LIU, Albany, NY (US); Steven GRZESKOWIAK, Albany, NY (US)

(73) Assignee: Tokyo Electron Limited, Tokyo (JP)

(21) Appl. No.: 18/798,099

(22) Filed: Aug. 8, 2024

(51) Int. Cl. H01L 21/033; H01L 21/311

(52) U.S. Cl. CPC H01L 21/0337; H01L 21/31144

(57) ABSTRACT

A method of manufacturing a semiconductor device is provided. The method includes providing a substrate that includes a layer stack and pillars formed on the layer stack. The pillars are spaced apart from each other. A spacer material is deposited to form a respective spacer film around a respective side surface of each of the pillars so that two neighboring spacer films merge with each other, leaving a recess in the spacer material. The spacer material is used as an etching mask for etching to form a hole in the layer stack. The hole is positioned below and aligned with the recess.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Extreme ultraviolet lithography (EUVL) is a relatively new technology used in the semiconductor industry for manufacturing integrated circuits. It is a type of photolithography that uses extreme ultraviolet (EUV) light to create intricate patterns on wafers.

### SUMMARY

The present disclosure relates to a method of forming a semiconductor device.

The method includes providing a substrate that includes a layer stack and pillars formed on the layer stack. The pillars are spaced apart from each other. A spacer material is deposited to form a respective spacer film around a respective side surface of each of the pillars so that two neighboring spacer films merge with each other, leaving a recess in the spacer material. The spacer material is used as an etching mask for etching to form a hole in the layer stack. The hole is positioned below and aligned with the recess.

In some embodiments, a shape of the hole is different from a shape of the recess.

In some embodiments, the recess has pointed edges in a horizontal plane parallel to a working surface of the substrate, and the hole is elliptical or circular in the horizontal plane.

In some embodiments, the hole is smaller than the recess in the horizontal plane.

In some embodiments, the depositing the spacer material is terminated when the two neighboring spacer films start to merge with each other.

In some embodiments, the depositing the spacer material is continued after the two neighboring spacer films have merged with each other.

In some embodiments, the pillars include at least a first pillar, a second pillar, a third pillar and a fourth pillar. The first pillar is respectively adjacent to the second pillar and the third pillar. The fourth pillar is respectively adjacent to the second pillar and the third pillar. The depositing the spacer material includes forming a first spacer film, a second spacer film, a third spacer film and a fourth spacer film around respective side surfaces of the first pillar, the second pillar, the third pillar and the fourth pillar. The first spacer film merges respectively with the second spacer film and the third spacer film. The fourth spacer film merges respectively with the second spacer film and the third spacer film.

In some embodiments, the recess includes a first sidewall formed of the first spacer film, a second sidewall formed of the second spacer film, a third sidewall formed of the third spacer film, and a fourth sidewall formed of the fourth spacer film.

In some embodiments, the depositing the spacer material further includes forming a bottom spacer film on an exposed surface of the layer stack. The recess further includes a bottom formed of the bottom spacer film.

In some embodiments, the first pillar, the second pillar, the third pillar and the fourth pillar are cylindrical. The recess is between four touching cylinders formed by the first spacer film, the second spacer film, the third spacer film and the fourth spacer film. The hole is substantially cylindrical.

In some embodiments, the first spacer film is spaced apart from the fourth spacer film, and the second spacer film is spaced apart from the third spacer film.

In some embodiments, the first pillar, the second pillar, the third pillar and the fourth pillar are arranged in a square or hexagonal pattern.

In some embodiments, the depositing the spacer material further includes forming a bottom spacer film on an exposed surface of the layer stack. The recess includes two sidewalls formed by the two neighboring spacer films that merge with each other, and a bottom formed of the bottom spacer film.

In some embodiments, the etching includes performing a first etching process to expose the layer stack while retaining part of the two sidewalls of the two neighboring spacer films.

In some embodiments, the etching further includes performing a second etching process to form the hole in the layer stack using the part of the two sidewalls of the two neighboring spacer films as an etching mask.

In some embodiments, the pillars are formed on the layer stack by extreme ultraviolet lithography (EUVL).

In some embodiments, the pillars include a metal oxide resist of the EUVL.

In some embodiments, the depositing the spacer material includes atomic layer deposition (ALD).

In some embodiments, the spacer material includes at least one selected from the group consisting of silicon oxide, silicon nitride, amorphous silicon, silicon oxynitride, silicon carbide, a metal oxide, a metal nitride and a metal.

In some embodiments, the layer stack includes a silicon-based anti-reflective coating below the pillars and an optical planarization layer below the silicon-based anti-reflective coating.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a flow chart of a process for manufacturing a semiconductor device, in accordance with some embodiments of the present disclosure.

FIGS. 2A, 3A and 4A show top-down views of a semiconductor device at various intermediate steps of manufacturing, in accordance with some embodiments of the present disclosure.

FIG. 2B shows a vertical cross-sectional view taken along the line cut AA′ in FIG. 2A in accordance with one embodiment of the present disclosure.

FIG. 3B shows a vertical cross-sectional view taken along the line cut BB′ in FIG. 3A in accordance with one embodiment of the present disclosure.

FIG. 4B shows a vertical cross-sectional view taken along the line cut CC′ in FIG. 4A in accordance with one embodiment of the present disclosure.

FIGS. 5A, 5B, 5C and 5D show data of semiconductor devices in accordance with some embodiments of the present disclosure.

FIGS. 6A and 6B show top-down views of a semiconductor device at various intermediate steps of manufacturing, in accordance with some embodiments of the present disclosure.

FIG. 7 shows data of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

In advanced nodes, dense channel patterns formed by extreme ultraviolet (EUV) lithography are often used for high volume manufacturing (HVM). However, pattern performance, especially critical dimension (CD) and local CD uniformity (LCDU) shrink, has become quite a challenge. Edge placement error (EPE) control is critical for node scaling, and local variability is a main contributor to EPE.

According to aspects of the present disclosure, pillars are formed on a layer stack by extreme ultraviolet lithography (EUVL). A spacer material can then be conformally deposited by ALD to form spacer films around side surfaces of the pillars so that two neighboring spacer films merge with each other, leaving a recess in the spacer material. The spacer material can for example merge the shortest distance between two neighboring pillars. The spacer material can then be used as an etching mask to form a hole in the layer stack, therefore transferring the recess pattern from the spacer material to the hole pattern in the layer stack. The hole is positioned below and aligned with the recess. The shape of the hole is determined by the shape of the recess and yet may be different from the shape of the recess due to plasma smoothing.

Techniques herein leverage negative tone development (NTD) photoresist that has high EUV sensitivity for pillar formation. A spacer material can be formed around EUV NTD pillars and merge with itself to form a small and uniform hole pattern with reliable fidelity including contact edge roughness (CER), LCDU, extremely size shrink, etc. Techniques herein further leverage plasma smoothing and atomic layer deposition (ALD) smoothing to improve the LCDU and achieve a smaller CD target without entering the trade-off between CD and LCDU. Techniques herein may only add a single low-cost step to the overall process flow and are capable of being adapted in other advance node EUV patterning processing including both single exposure and multi-patterning.

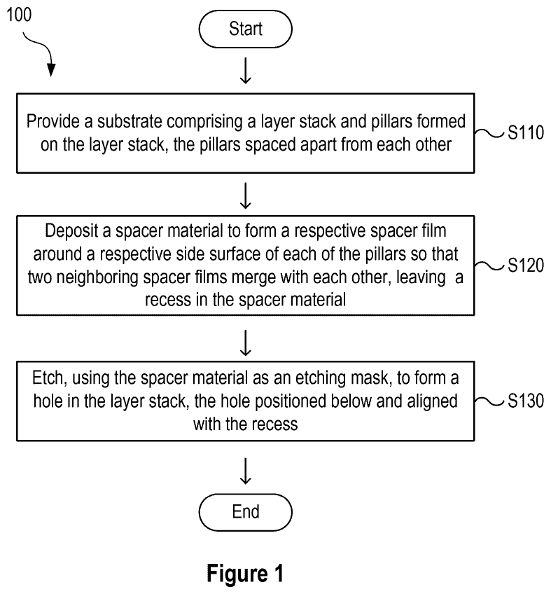

FIG. 1 shows a flow chart of a process 100 for manufacturing a semiconductor device in accordance with some embodiments of the present disclosure. At step S110, a substrate is provided by oneself or a third party. The substrate includes a layer stack and pillars formed on the layer stack. The pillars are spaced apart from each other. At step S120, a spacer material is deposited to form a respective spacer film around a respective side surface of each of the pillars so that two neighboring spacer films merge with each other, leaving a recess in the spacer material. At step S130, the spacer material is used as an etching mask for etching to form a hole in the layer stack. The hole is positioned below and aligned with the recess.

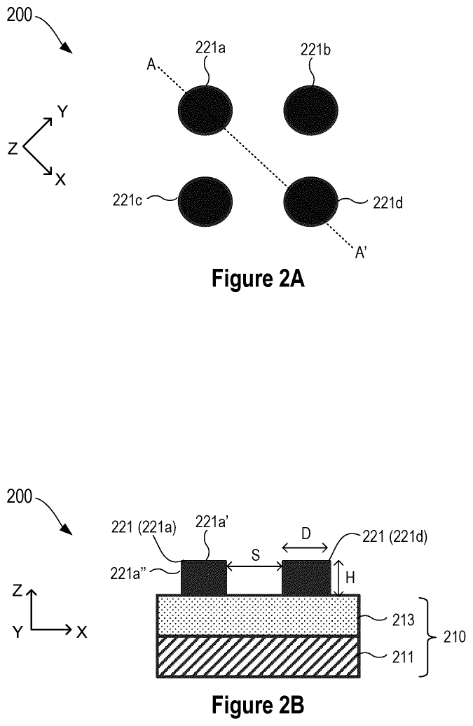

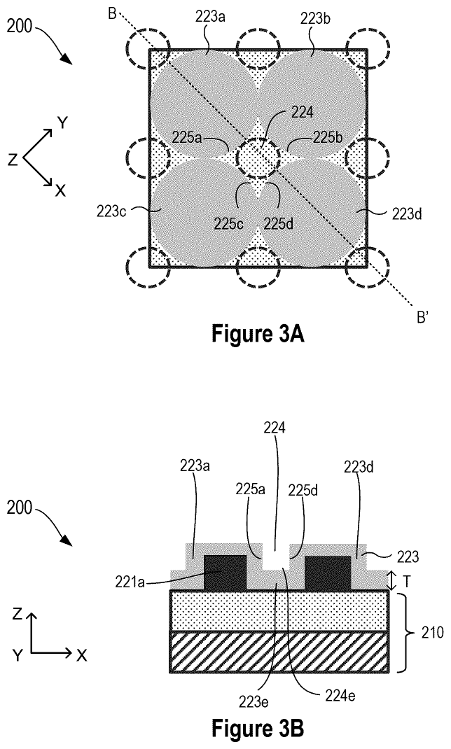

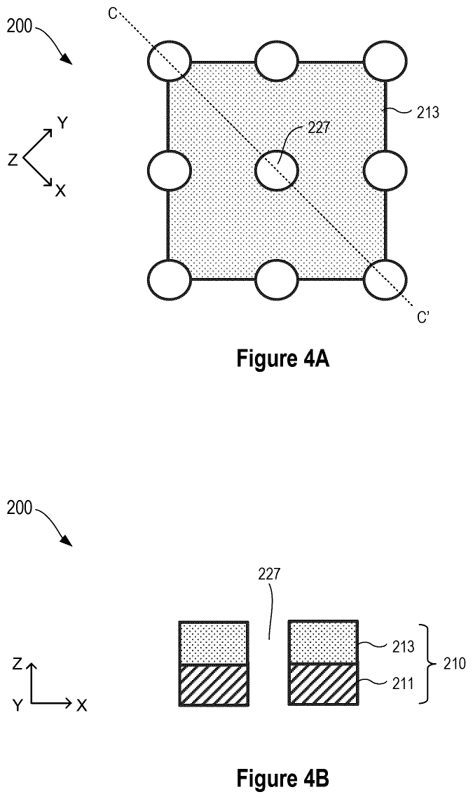

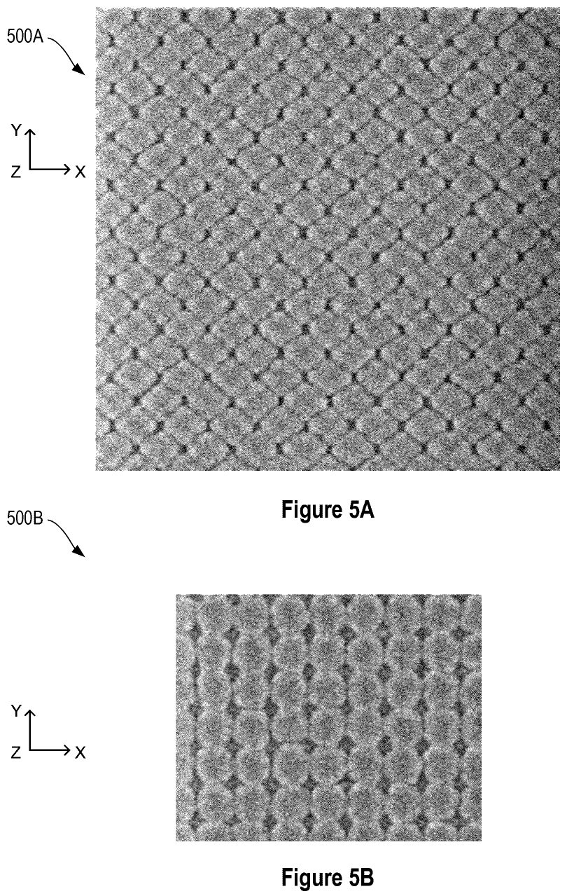

FIGS. 2A, 3A and 4A show top-down views of a semiconductor device 200 at various intermediate steps of manufacturing, FIG. 2B shows a vertical cross-sectional view taken along the line cut AA′ in FIG. 2A, FIG. 3B shows a vertical cross-sectional view taken along the line cut BB′ in FIG. 3A, and FIG. 4B shows a vertical cross-sectional view taken along the line cut CC′ in FIG. 4A, in accordance with some embodiments of the present disclosure.

As shown in FIGS. 2A and 2B, the semiconductor device 200 can include a layer stack 210 and pillars 221 formed on the layer stack 210. The layer stack 110 includes one or more layers stacked in the Z direction. For example, the layer stack 110 can include an organic planarization layer (OPL) 211 (also known as an optical planarization layer) and a silicon-based anti-reflective coating (SiARC) 213 (e.g. silicon oxide). The pillars 221 can include a metal oxide resist (MOR) that is used for extreme ultraviolet lithography (EUVL).

To obtain the semiconductor device 200, a layer of the MOR can be formed on the layer stack 210, resulting in a tri-layer stack consisting of the layer of the MOR, the SiARC 213 and the OPL 211. Then, EUVL can be executed with a darkfield mask to form the (NTD) pillars 221. As a result, local critical dimension uniformity (LCDU) of 2 nm or less can be achieved on a 36 nm pitch pattern.

In the example of FIG. 2A, the pillars 221 include at least four pillars, such as a first pillar 221a, a second pillar 221b, a third pillar 221c and a fourth pillar 221d. Herein, the at least four pillars are cylindrical and arranged in a square pattern in the XY plane. The first pillar 221a is respectively adjacent to the second pillar 221b and the third pillar 221c. The fourth pillar 221d is respectively adjacent to the second pillar 221b and the third pillar 221c. The first pillar 221a and the fourth pillar 221d are diagonal to each other. The pillars 221 each have a respective side surface (e.g. 221a″) and a respective top surface (e.g. 221a′).

The pillars 221 can have a diameter D of 2-20 nm in the XY plane, e.g. 2 nm, 3 nm, 5 nm, 7.5 nm, 10 nm, 12.5 nm, 15 nm, 17.5 nm, 20 nm or any values therebetween. The pillars 221 can have a height H of 5-30 nm in the Z direction, e.g. 5 nm, 7.5 nm, 10 nm, 15 nm, 20 nm, 25 nm, 30 nm or any values therebetween. The pillars 221 can have a spacing S of 5-25 nm in the XY plane, e.g. 5 nm, 7.5 nm, 10 nm, 15 nm, 20 nm, 25 nm or any values therebetween. The height H can be equal to or larger than the diameter D. An aspect ratio of H/D can be 1-10, e.g. 1, 1.5, 2, 2.5, 3, 5, 7.5, 10 or any values therebetween. In a non-limiting example, D is about 15 nm. H is about 20 nm. S is about 16 nm. It should be understood that dimensions and spacings of the pillars 221 are not particularly limited. The ranges and values are provided herein merely for illustrative purposes.

Note that the SiARC 213 is visible in a top-down view of the semiconductor device 200. However, the SiARC 213 is omitted from FIG. 2A in order to show the pillars 221 better.

In FIGS. 3A and 3B, a spacer material 223 is deposited. For example, silicon oxide can be deposited by an atomic layer deposition (ALD) process. As a result, the spacer material 223 can be conformally formed on the pillars 221 and the SiARC 213. Particularly, a first spacer film 223a, a second spacer film 223b, a third spacer film 223c and a fourth spacer film 223d can be respectively formed around the first pillar 221a, the second pillar 221b, the third pillar 221c and the fourth pillar 221d. A respective spacer film (e.g. 223a) can cover a respective side surface (e.g. 221a″) of each pillar (e.g. 221a) as well as a respective top surface (e.g. 221a′) of each pillar (e.g. 221a). A bottom spacer film 223e can be formed on the layer stack 210.

The ALD process, or rather the deposition of the spacer material 223, can be terminated when two neighboring spacer films (e.g. 223a and 223b) merge with each other, which leaves a recess 224 in the spacer material 223. Therefore, the spacer material 223 can have a thickness T that is about half the spacing S. T=S/2. When S is about 16 nm, T is about 8 nm.

In this example, the first spacer film 223a merges respectively with the second spacer film 223b and the third spacer film 223c. The fourth spacer film 223d merges respectively with the second spacer film 223b and the third spacer film 223c. The first spacer film 223a is spaced apart from the fourth spacer film 223d. The second spacer film 223b is spaced apart from the third spacer film 223c.

The recess 224 includes a first sidewall 225a formed of the first spacer film 223a, a second sidewall 225b formed of the second spacer film 223b, a third sidewall 225c formed of the third spacer film 223c, and a fourth sidewall 225d formed of the fourth spacer film 223d. The recess 224 also includes a bottom 224e formed of the bottom spacer film 223e. When the pillars 221 are cylindrical, the recess 224 can represent a space between four touching cylinders. In the top-down view of FIG. 3A along a XY cross-section, the recess 224 may represent a space between four touching circles, as a skilled artisan would understand.

Note that the SiARC 213 covered by the pillars 221 and the spacer material 223 is not visible in a top-down view of the semiconductor device 200. However, the SiARC 213 is shown in FIG. 3A, with the bottom spacer film 223e omitted, in order to show the recess 224 better. Additionally, dotted circles are added to FIG. 3A in order to show the recess 224 better and do not represent actual shapes formed by ALD.

In FIGS. 4A and 4B, the spacer material 223 is used as an etching mask for etching to form a hole 227 in the layer stack 210. As a result, a recess pattern from the spacer material 223 is transferred to a hole pattern in the layer stack 210. Note that the hole pattern can be positioned below and aligned with the recess pattern. However, a shape of the hole 227 may be different from a shape of the recess 224 due to the plasma smoothing effect. This is different from traditional patterning where when one pattern is transferred from one layer to another, the pattern is substantially unchanged or intact, corresponding to high pattern fidelity in traditional patterning.

Herein, plasma species (e.g. ions, electrons and/or radicals) can be less concentrated around pointed edges of the recess 224, which leads to a smaller (or even negligible) etching rate around the pointed edges of the recess 224 and thus smooths the pointed edges of the recess 224 during etching and results in a lower contact edge roughness (CER). Consequently, the shape of the hole 227 is smoother, or rather more circular, than the shape of the recess. By adjusting the etching parameters, the shape of the hole 227 can be substantially circular with a diameter d of 1-15 nm in the XY plane, e.g. 1 nm, 2 nm, 3 nm, 5 nm, 7.5 nm, 10 nm, 12.5 nm, 15 nm or any values therebetween. In a non-limiting example, the shape of the hole 227 may be the same as or substantially similar to the dotted circle(s) in FIG. 3A, with d=(\sqrt{2}-1)(D+S).

In one embodiment, a dry etching process using the chemistry of CF₄/CHF₃ can be utilized to directionally (e.g. along the Z direction) etch the spacer material 223 and open the ALD silicon oxide (e.g. 223) and the SiARC 213, followed by SO₂/O₂ chemistry to open the OPL 211. The pillars 221 can then be removed. The pattern is ready for mask transfer for more processing. Through this spacer merging technique and etch transfer, LCDU and CER can be improved.

In another embodiment, a first etching process can be executed to directionally (e.g. along the Z direction) etch the spacer material 223 so that the bottom spacer film 223e is removed to expose the SiARC 213 while partially retaining the first spacer film 223a, the second spacer film 223b, the third spacer film 223c and the fourth spacer film 223d. That is, the first spacer film 223a, the second spacer film 223b, the third spacer film 223c and the fourth spacer film 223d are respectively thicker than the bottom spacer film 223e. As a result, when the bottom spacer film 223e is etched away, the first spacer film 223a, the second spacer film 223b, the third spacer film 223c and the fourth spacer film 223d can partially remain on side surfaces of the pillars 221. Subsequently, the (remaining) first spacer film 223a, the (remaining) second spacer film 223b, the (remaining) third spacer film 223c and the (remaining) fourth spacer film 223d can be used as an etching mask to etch one or more layers of the layer stack 210 to form the hole 227 before being etch away.

Still referring to FIGS. 2A, 2B, 3A, 3B, 4A and 4B, it should be understood that the pillars 221 may include any number of pillars or more than four pillars. The pillars 221 can be arranged in the XY plane in various patterns such as equilateral patterns that include, but are not limited to, a triangular pattern, a square pattern, a pentagonal pattern, a hexagonal pattern, etc. For instance in the case of an equilaterally pentagonal pattern, a recess can be formed between five touching cylinders similar to the four touching cylinders in FIG. 3A, as a skilled artisan would understand. The pillars 221 are preferably cylindrical but can have other shapes as well. For instance, the pillars 221 can have an elliptical shape in the XY plane so the corresponding recess is formed between four touching ellipses, resulting in an elliptical hole in the layer stack 210.

While the SiARC 213 and the OPL 211 are shown here for illustrative purposes, the layer stack 210 may include any number of layers having various materials. A top layer of the layer stack 210, which is immediately below and in contact with the pillars 221, can be configured to be etch-selective to the pillars 221. The top layer of the layer stack 210 can include silicon nitride for example.

Similarly, the spacer material 223 is not particularly limited and can include various materials that enable selective etching chemistry and satisfy the etching process(es) in FIGS. 4A and 4B. The spacer material 223 can include, but are not limited to, silicon nitride, amorphous silicon, silicon oxide, silicon oxynitride, silicon carbide, a metal oxide (e.g. zinc oxide, tin oxide, indium oxide, titanium oxide, copper oxide, etc.), a metal nitride (e.g. titanium nitride, aluminum nitride, tantalum nitride, niobium nitride, etc.), a metal (e.g. iron, cobalt, nickel, copper, etc.) and/or the like. Accordingly, the etching process can utilize various gas species including, but not limited to, CF₄, CHF₃, CH₂F₂, CH₃F, SF₆, NF₃, O₂, N₂, H₂, Cl₂, HBr, CₓF_{y}, BCl₃, SO₂, CO₂, CO, CH₄ and/or the like.

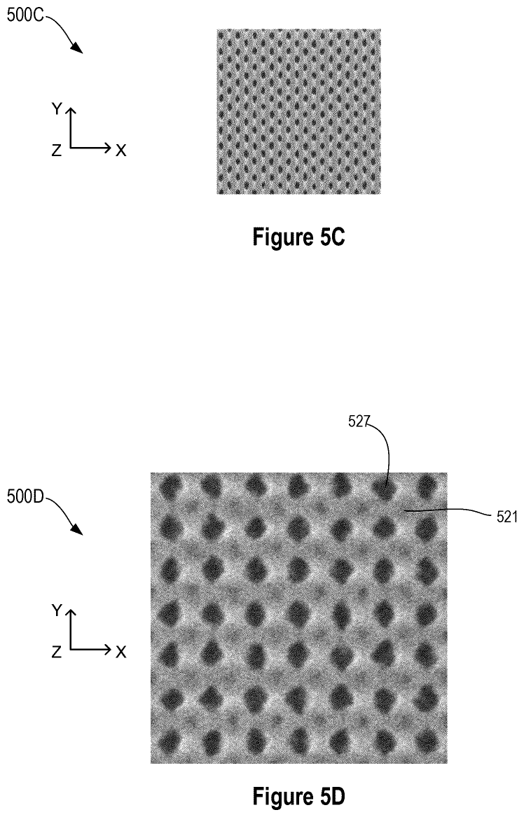

FIGS. 5A, 5B, 5C and 5D show data of semiconductor devices in accordance with some embodiments of the present disclosure. FIG. 5A shows a semiconductor device 500A manufactured by processes shown in FIGS. 2A, 2B, 3A and 3B, with pillars arranged in a hexagonal pattern and spacer films merged. FIG. 5B shows a semiconductor device 500B manufactured by processes shown in FIGS. 2A, 2B, 3A and 3B, with pillars arranged in a square pattern and spacer films merged. FIG. 5C shows a semiconductor device 500C manufactured by processes shown in FIGS. 2A, 2B, 3A, 3B, 4A and 4B, with holes formed. FIG. 5D shows a semiconductor device 500D manufactured by processes shown in FIGS. 2A, 2B, 3A, 3B, 4A and 4B, with holes (e.g. 527) formed and pillars (e.g. 521) to be removed.

Referring back to FIGS. 3A and 3B, the ALD process, or rather the deposition of the spacer material 223, can be terminated when two neighboring spacer films (e.g. 223a and 223b) merge with each other. Therefore, T=S/2.

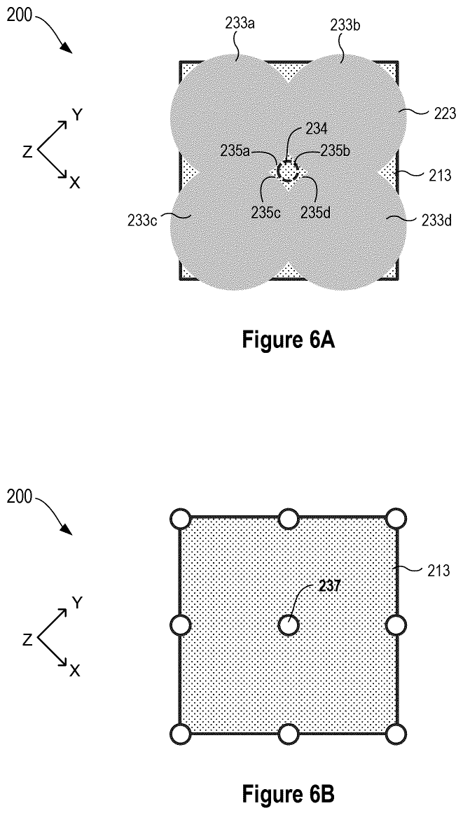

In an alternative embodiment as shown in FIG. 6A, the ALD process, or rather the deposition of the spacer material 223, can be continued after the two neighboring spacer films (e.g. 223a and 223b) have merged with each other. As a result, a recess 234 is formed, and T>S/2. Accordingly, the recess 234 herein is smaller in the XY plane than the recess 224 in FIGS. 3A and 3B.

Similarly, the recess 234 includes a first sidewall 235a formed of the first spacer film 223a, a second sidewall 235b formed of the second spacer film 223b, a third sidewall 235c formed of the third spacer film 223c, and a fourth sidewall 235d formed of the fourth spacer film 223d.

Note that the SiARC 213 covered by the pillars 221 and the spacer material 223 is not visible in a top-down view of the semiconductor device 200. However, the SiARC 213 is shown in FIG. 6A, with the bottom spacer film 223e omitted, in order to show the recess 234 better, similar to FIG. 3A. Additionally, a dotted circle is added to FIG. 6A in order to show the recess 234 better and does not represent an actual shape formed by ALD.

In FIG. 6B, the spacer material 223 is used as an etching mask for etching to form a hole 237 in the layer stack 210. The hole 237 herein is smaller in the XY plane than the hole 227 in FIGS. 4A and 4B. The hole 237 may have a diameter of smaller than 5 nm. The embodiments of FIGS. 6A and 6B provide an additional knob for hole CD control by the ALD thickness to achieve precise hole CD control.

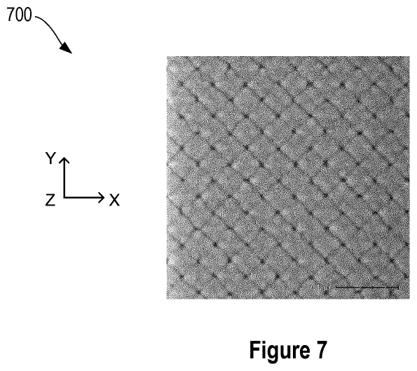

FIG. 7 shows data of a semiconductor device 700 manufactured by processes shown in FIGS. 2A, 2B, 6A and 6B, with holes formed.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of manufacturing a semiconductor device, the method comprising:
providing a substrate comprising a layer stack and pillars formed on the layer stack, the pillars spaced apart from each other;
depositing a spacer material to form a respective spacer film around a respective side surface of each of the pillars so that two neighboring spacer films merge with each other, leaving a recess in the spacer material; and
etching, using the spacer material as an etching mask, to form a hole in the layer stack, the hole positioned below and aligned with the recess.

2. The method of claim 1, wherein:
a shape of the hole is different from a shape of the recess.

3. The method of claim 2, wherein:
the recess has pointed edges in a horizontal plane parallel to a working surface of the substrate, and
the hole is elliptical or circular in the horizontal plane.

4. The method of claim 3, wherein:
the hole is smaller than the recess in the horizontal plane.

5. The method of claim 1, wherein:
the depositing the spacer material is terminated when the two neighboring spacer films start to merge with each other.

6. The method of claim 1, wherein:
the depositing the spacer material is continued after the two neighboring spacer films have merged with each other.

7. The method of claim 1, wherein:
the pillars comprise a first pillar, a second pillar, a third pillar and a fourth pillar, where the first pillar is respectively adjacent to the second pillar and the third pillar, and the fourth pillar is respectively adjacent to the second pillar and the third pillar, and
the depositing the spacer material comprises forming a first spacer film, a second spacer film, a third spacer film and a fourth spacer film around respective side surfaces of the first pillar, the second pillar, the third pillar and the fourth pillar,
the first spacer film merges respectively with the second spacer film and the third spacer film, and
the fourth spacer film merges respectively with the second spacer film and the third spacer film.

8. The method of claim 7, wherein the recess comprises:
a first sidewall formed of the first spacer film;
a second sidewall formed of the second spacer film;
a third sidewall formed of the third spacer film; and
a fourth sidewall formed of the fourth spacer film.

9. The method of claim 8, wherein:
the depositing the spacer material further comprises forming a bottom spacer film on an exposed surface of the layer stack, and
the recess further comprises a bottom formed of the bottom spacer film.

10. The method of claim 7, wherein:
the first pillar, the second pillar, the third pillar and the fourth pillar are cylindrical,
the recess is between four touching cylinders formed by the first spacer film, the second spacer film, the third spacer film and the fourth spacer film, and
the hole is substantially cylindrical.

11. The method of claim 7, wherein:
the first spacer film is spaced apart from the fourth spacer film, and
the second spacer film is spaced apart from the third spacer film.

12. The method of claim 7, wherein:
the first pillar, the second pillar, the third pillar and the fourth pillar are arranged in a square or hexagonal pattern.

13. The method of claim 1, wherein:
the depositing the spacer material further comprises forming a bottom spacer film on an exposed surface of the layer stack, and
the recess comprises:
two sidewalls formed by the two neighboring spacer films that merge with each other; and
a bottom formed of the bottom spacer film.

14. The method of claim 1, wherein the etching comprises:
performing a first etching process to expose the layer stack while retaining part of the two sidewalls of the two neighboring spacer films.

15. The method of claim 14, wherein the etching further comprises:
performing a second etching process to form the hole in the layer stack using the part of the two sidewalls of the two neighboring spacer films as an etching mask.

16. The method of claim 1, further comprising:
forming the pillars on the layer stack by extreme ultraviolet lithography (EUVL).

17. The method of claim 16, wherein:
the pillars comprise a metal oxide resist of the EUVL.

18. The method of claim 1, wherein:
the depositing the spacer material comprises atomic layer deposition (ALD).

19. The method of claim 18, wherein:
the spacer material includes at least one selected from the group consisting of silicon oxide, silicon nitride, amorphous silicon, silicon oxynitride, silicon carbide, a metal oxide, a metal nitride and a metal.

20. The method of claim 1, wherein:
the layer stack comprises a silicon-based anti-reflective coating below the pillars and an optical planarization layer below the silicon-based anti-reflective coating.
